(19) United States
(12) Patent Application Publication
(10) Pub. No.: US 2005/0077538 A1
(43) Pub. Date: Apr. 14, 2005

(54) Design methodology for multiple channel heterostructures in polar materials

(75) Inventor: Sten Johan Heikman, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: The Regents of the University of California

(21) Appl. No.: 10/962,856

(22) Filed: Oct. 12, 2004

Related U.S. Application Data
(60) Provisional application No. 60/510,691, filed on Oct. 10, 2003.

(51) Int. Cl. H01L 21/00; H01L 29/22; H01L 33/00; H01L 31/072; H01L 35/26

(52) U.S. Cl. 257/183; 438/47; 438/172; 257/94

(57) ABSTRACT

A method for fabricating multiple channel heterostructures with high sheet carrier densities in each channel, while maintaining a low energy barrier for transfer of majority carriers between the channels. For a heterostructure where n-type conductivity is desired, n-type dopant impurities are placed at each heterointerface with negative polarization charge, equal in magnitude to the negative polarization charge. For a heterostructure where p-type conductivity is desired, p-type dopant impurities are placed at each heterointerface with positive polarization charge, equal in magnitude to the positive polarization charge. The heterointerfaces with dopant impurities can be graded in chemical composition, over a certain distance, while the dopant impurities are distributed along the graded distance. The heterointerfaces with dopant impurities can also be abrupt, in which case the dopant impurity is located in a sheet or thin layer at or near the heterointerface.

### CROSS-REFERENCE TO RELATED APPLICATIONS

This application claims the benefit under 35 U.S.C. § 19(e) of the following co-pending and commonly-assigned U.S. Provisional Patent Application: Ser. No. 60/510,691, entitled “DESIGN METHODOLOGY FOR MULTIPLE CHANNEL HETEROSTRUCTURES IN POLAR MATERIALS,” filed on Oct. 10, 2003, by Sten J. Heikman, attorneys docket number 30794.106-US-PI; which application is incorporated by reference herein.

### STATEMENT REGARDING FEDERALLY SPONSORED RESEARCH AND DEVELOPMENT

This invention was made with Government support under Grant No. N00014-01-1-0764 awarded by the ONR MURI program and Grant No. F49620-99-1-0296 awarded by the AFOSR MURI program. The Government has certain rights in this invention.

### BACKGROUND OF THE INVENTION

1. Field of the Invention

This invention relates to semiconductor devices, and more particularly, to a design methodology for multiple channel heterostructures in polar materials.

2. Description of the Related Art

In existing practice, multiple channel structures are seldom employed for the purpose of increasing the total charge in a heterostructure. In GaAs and InP based structures, which are non-polar for the commonly used substrate orientations, the doping required to generate charge in the channels also creates a barrier for charge transfer between the channels. The barrier is a result of the band-curvature associated with the ionization of the doping elements. In GaN/AlGaN based heterostructures, bulk doping is presently not used as a major source of carriers; most carriers originate from surface donors. Without bulk doping, adding AlGaN/GaN layers to the structure, to create additional channels, does not increase the total charge in the structure; instead, adding an additional AlGaN/GaN bi-layer on top of a single AlGaN/GaN structure would lead to a severely depleted upper channel, and a somewhat depleted lower channel.

What is needed, then, are improved methods of fabricating multiple channel heterostructures with high sheet carrier density in each channel, and a low energy barrier for charge transfer between the channels, in a polar material system. The present invention places n-type doping impurities at the interface between each AlGaN layer followed by a GaN layer (from bottom to top), equal in magnitude to the polarization charge arising from the Al composition change. This design methodology permits high charge in each channel of a multiple channel heterostructure, without creating large energy barriers for carrier transfer between channels.

### SUMMARY OF THE INVENTION

To overcome the limitations in the prior art described above, and to overcome other limitations that will become apparent upon reading and understanding the present specification, the present invention discloses a method for fabricating multiple channel heterostructures with high sheet carrier densities in each channel, while maintaining a low energy barrier for transfer of majority carriers between the channels. Such heterostructures can exhibit high conductivity both laterally and vertically, and has applications as current spreading layer in vertical devices, such as laser diodes and LEDs, and as high conductance access regions in FETs, bipolar transistors, and diodes.

According to the invention, for a heterostructure where n-type conductivity is desired, n-type dopant impurities are placed at each heterointerface with negative polarization charge, equal in magnitude to the negative polarization charge. For a heterostructure where p-type conductivity is desired, p-type dopant impurities are placed at each heterointerface with positive polarization charge, equal in magnitude to the positive polarization charge. The heterointerfaces where the dopant impurities are placed can be graded in chemical composition, over a certain distance, while the dopant impurities are distributed along the graded distance. The heterointerfaces where the dopant impurities are placed can also be non-linear, non-uniform or abrupt. In the case of an abrupt interface, the dopant impurities are placed in a sheet, or in a thin layer, located at or near the heterointerface.

### BRIEF DESCRIPTION OF THE DRAWINGS

Referring now to the drawings in which like reference numbers represent corresponding parts throughout:

FIG. 1 illustrates an AlGaN/GaN multiple channel heterostructure;

FIG. 2 illustrates a band diagram of a double channel AlGaN/GaN heterostructure;

FIG. 3 illustrates a conduction band edge of an AlGaAs/GaAs structure, doped to 2×10¹⁸ cm⁻² in the AlGaAs;

FIGS. 4 and 5 illustrate a simulated band diagram of a double channel Al_{0.32}Ga_{0.68}N/GaN heterostructure;

FIG. 6 illustrates a conduction band edge for uniform n-type doping in a graded region;

FIG. 7 illustrates an n-type doping sheet (3×10¹² cm⁻² sheet density) inserted at a lower edge of the graded region, followed by 8 nm of uniform n-type doping; and

FIG. 8 is a flowchart that illustrates the steps for fabricating multiple channel heterostructures with high sheet carrier densities in each channel, while maintaining a low energy barrier for transfer of carriers between the channels, according to the preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention allows for the fabrication of multiple channel heterostructures with a high sheet carrier density in each channel, and a low energy barrier for charge transfer between the channels, in a polar material system. Applications of the structure include, but are not limited to, high conductance source and drain access regions in AlGaN/GaN high electron mobility transistors (HEMTs), and current spreading layers in III-Nitride laser diodes and light emitting diodes (LEDs).

General Description

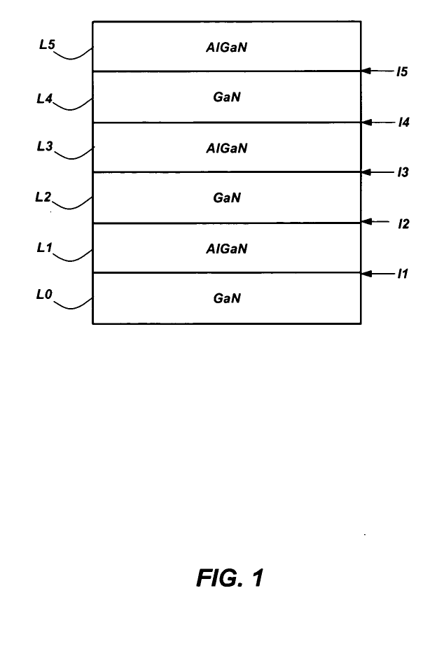

An AlGaN/GaN multiple channel heterostructure is illustrated in FIG. 1, to be used as an example in describing the invention. The heterointerfaces are labeled I1, I2, I3, I4 and I5, and the GaN and AlGaN layers are labeled L0, L1, L2, L3, L4 and L5, from bottom to top. In the special case of a double channel structure, only two AlGaN layers (L1 and L3) and three interfaces (I1, I2 and I3) are present. In the example, the structure is assumed to be deposited in the (0001) GaN direction, with a Ga-polar top surface.

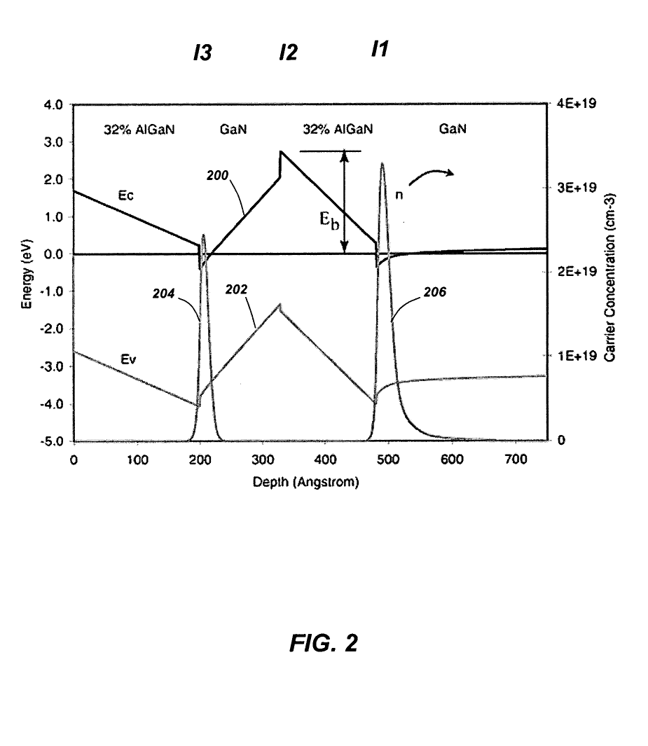

In the prior art, adding an additional AlGaN/GaN bi-layer on top of a single AlGaN/GaN structure would lead to a severely depleted upper channel, and a somewhat depleted lower channel. FIG. 2 illustrates the band diagram of a double channel AlGaN/GaN heterostructure, including the effects of polarization in the (0001) direction, wherein plots 200 and 202 represent the conduction band edge (Ec) and valence band edge (Ev), respectively, for Energy (eV) v.Depth (Angstrom), and plots 204 and 206 represents the carrier concentrations at the interfaces I3 and I1, respectively, for Carrier Concentration (cm-3) v. Depth (Angstrom). The aluminum mole fraction in the two AlGaN layers in the structure is 32%. At the lower AlGaN/GaN interface (I1), a 2-dimensional electron gas (2DEG) with a sheet carrier density of 8.9×10¹² cm⁻² is induced, and at the upper AlGaN/GaN interface (I3), a 2DEG with a sheet carrier density of 4.3×10¹² cm⁻² is induced.

The sheet carrier density in the two channels add up to 1.32×10¹³ cm⁻², which is approximately the same as a single channel structure (200 Å32% AlGaN layer on top of GaN) would induce at its single AlGaN/GaN interface. Thus, the double channel heterostructure does not increase the total charge in the structure. The free carrier densities present at interfaces I1 and I3 are induced (attracted) by fixed polarization charges at the interfaces. However, in the absence of intentional n-type doping in the structure, the carriers originate from surface donors [see, e.g., J. P. Ibbetson, P. T. Fini, K. D. Ness, S. P. DenBaars, J. S. Speck, and U. K. Mishra, “Polarization effects, surface states, and the source of electrons in AlGaN/GaN heterostructure field effect transistors”, Appl. Phys. Lett. 77, p. 250, 2000], a configuration which puts limits on the total charge in the structure.

The sum of the charge at the two interfaces I1 and I3 can be increased by increasing the distance between the two interfaces (by increasing the thickness of layers L1 and/or L2). This does, however, lead to an increased energy barrier in the conduction band edge (Ec), further preventing transfer of charge between the channels. The maximum conduction band edge barrier that can occur is approximately the full energy bandgap of the GaN; any increase in thickness beyond this point results in the formation of a 2-dimensional hole gas at interface I2, and pinning of the valence band edge at the Fermi-level at this interface.

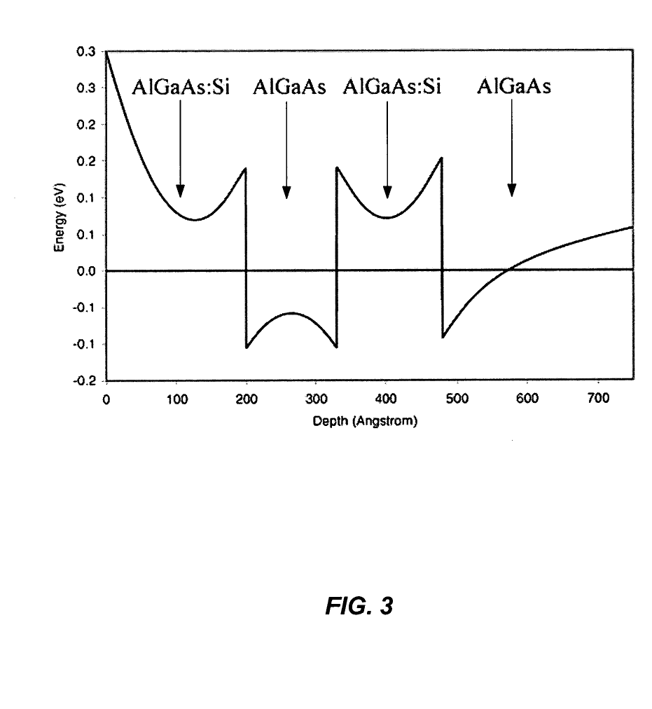

In heterostructures formed in non-polar material systems, such as AlGaAs/GaAs, the free carriers accumulated at heterointerfaces originate from impurity doping, typically located in the high bandgap material. Transfer of carriers from said impurities to the heterointerface by ionization of the impurities leads to parabolic band-curvature in the doped region. The conduction band edge of an AlGaAs/GaAs structure, doped to 2×10¹⁸ cm⁻² in the AlGaAs, is illustrated in FIG. 3. The band-curvature in the AlGaAs between the channels is inevitable, and it results in a barrier for charge transfer between the channels.

An AlGaN/GaN heterostructure grown on Ga-polar material will be used as an example to describe the present invention. The present invention is not limited to AlGaN/GaN heterostructures, but can be implemented in any polar material system.

The present invention involves placement of n-type doping at every even numbered GaN/AlGaN interface (I2, I4, etc.), equal in magnitude to the negative polarization charge present at the respective interfaces. The n-type doping, when ionized, serves to compensate the polarization charge, thus eliminating band-curvature at the interface. The n-type doping also serves to provide charge for the channels located at the odd (I1, I3, I5, etc.) AlGaN/GaN interfaces.

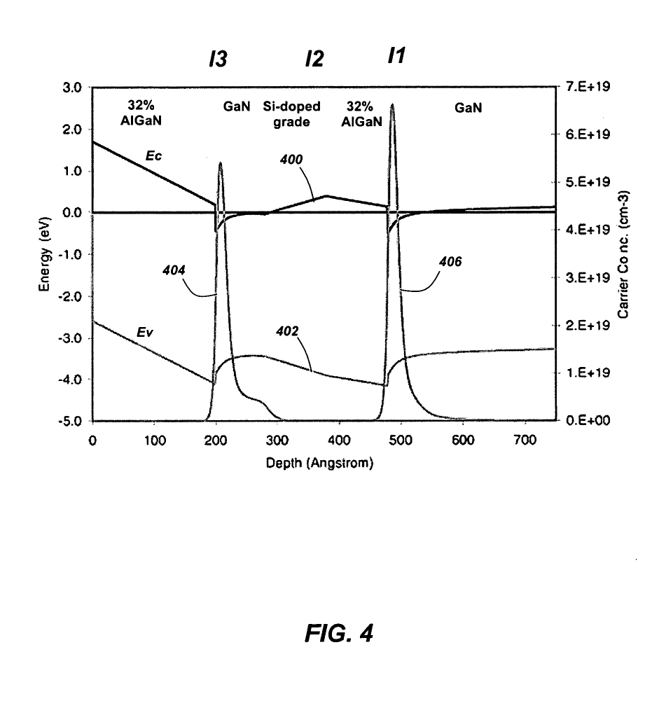

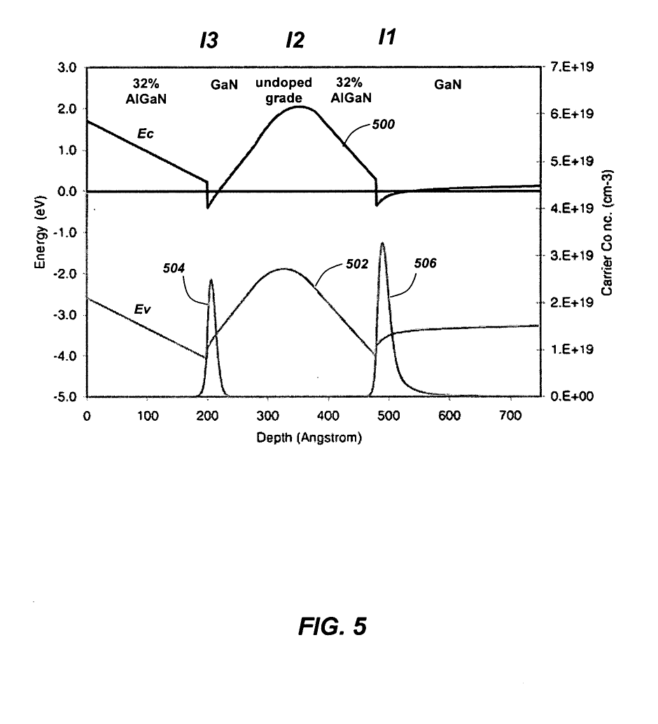

The simulated band diagram of a double channel Al_{0.32}Ga_{0.68}N/GaN heterostructure is illustrated in FIGS. 4 and 5. Here, the Al composition has been linearly graded from 32% AlGaN to GaN at interface I2, over a distance of 10 nm. In FIG. 4, n-type doping equal to the polarization charge is present in the graded region (I2), wherein plots 400 and 402 represent the conduction band edge (Ec) and valence band edge (Ev), respectively, for Energy (eV) v. Depth (Angstrom), and plots 404 and 406 represents the carrier concentrations for Carrier Concentration (cm-3) v. Depth (Angstrom).

FIG. 5 illustrates the case of an undoped graded region, as a comparison, wherein plots 500 and 502 represent the conduction band edge (Ec) and valence band edge (Ev), respectively, for Energy (eV) v. Depth (Angstrom), and plots 504 and 506 represents the carrier concentrations for Carrier Concentration (cm-3) v. Depth (Angstrom). In FIG. 5, the structure with undoped graded region, the sheet carrier density at interfaces I1 and I3 are 4.3×10¹² cm⁻² and 8.9×10¹² cm⁻², respectively, nearly identical to a device structure with an abrupt heterointerface I2. The barrier for majority carrier transfer between channels is approximately 2 eV. In FIG. 4, where the present invention is implemented (n-type doping at the graded interface), the sheet carrier density at interfaces I1 and I3 are 1.45×10¹³ cm⁻² and 1.56×10¹³ cm⁻², respectively, adding up to 3.01×10¹³ cm⁻². Furthermore, with the present invention implemented, the barrier for majority carrier transfer between channels is much reduced.

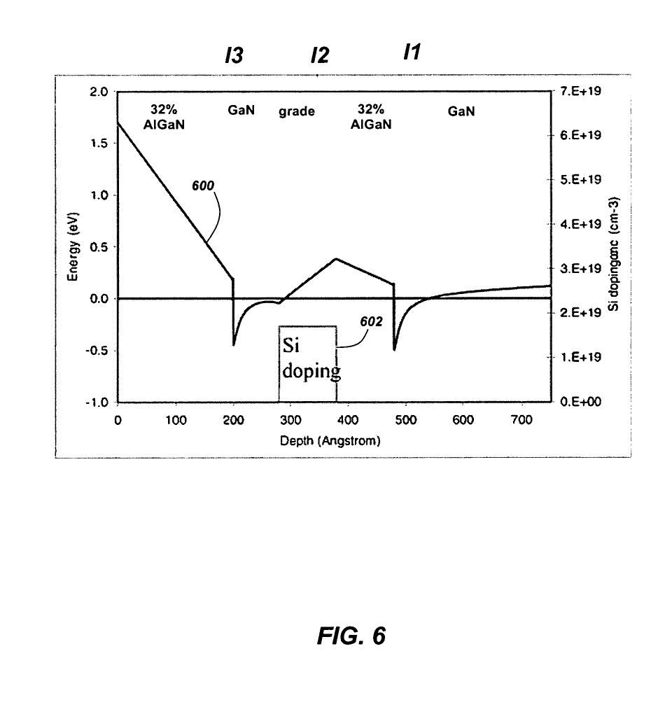

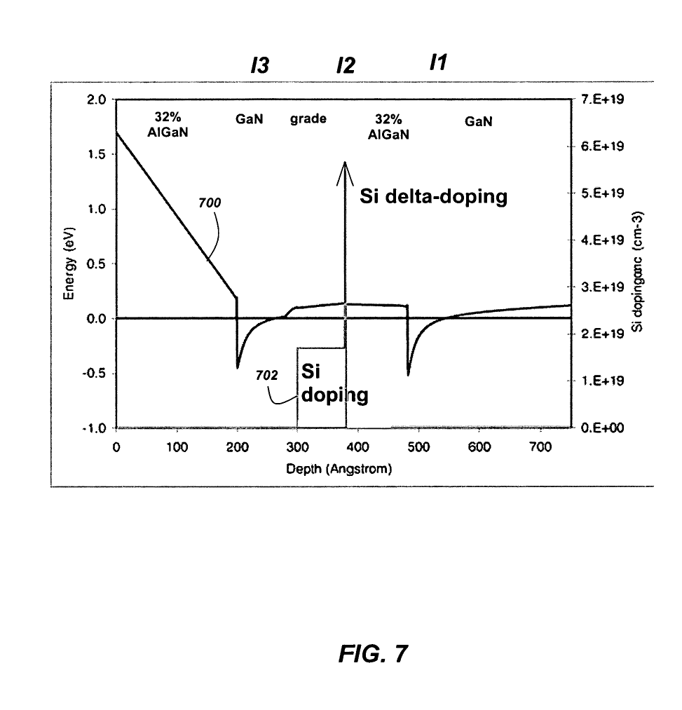

By modifying the n-type doping distribution, the exact shape of the conduction band edge can be tailored. FIG. 6 illustrates the conduction band edge for uniform n-type doping in the graded region, wherein plot 600 represents the conduction band edge (Ec) for Energy (eV) v. Depth (Angstrom), and plot 602 represents the carrier concentrations for Carrier Concentration (cm-3) v. Depth (Angstrom). In FIG. 7, an n-type doping sheet (3×10¹² cm⁻² sheet density) has been inserted at the lower edge of the graded region, followed by 8 nm of uniform n-type doping, wherein plot 700 represents the conduction band edge (Ec) for Energy (eV) v. Depth (Angstrom), and plot 702 represents the carrier concentrations for Carrier Concentration (cm-3) v. Depth (Angstrom). This doping distribution leads to a nearly flat conduction band edge between the two channels, with a very low energy barrier for charge transfer.

The best way of practicing the invention is in a double channel AlGaN/GaN heterostructure. The Al composition grade at interface I2 is linear, and the n-type doping is constant. The dopant element is Si.

The invention has been successfully demonstrated in the following layer structure, deposited on a sapphire substrate:

Surface
20 nm 35% AlGaN
0.6 nm AlN
8 nm GaN
10 nm 35% AlGaN -> GaN grade, Si doping 1.6 × 10¹⁹ cm⁻³
15 nm 35% AlGaN
0.6 nm AlN
2.6 μm semi-insulating GaN base layer
Sapphire

Hall effect measurements of the structure, performed contacting the entire depth of the structure, resulted in a sheet carrier density of 2.65×10¹³ cm⁻² , and a Hall mobility of 1560 cm²/V_{S}. This corresponds to a sheet resistance of 151 ohm/sq, which is far lower than what can currently be achieved with a single channel structure (typically around 260-300 ohm/sq).

Process Steps

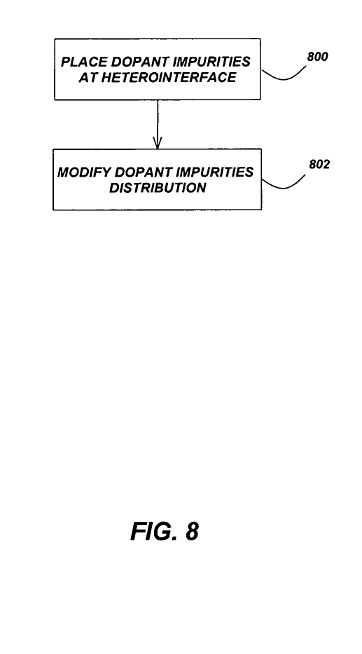

FIG. 8 is a flowchart that illustrates the steps for fabricating multiple channel heterostructures with high sheet carrier densities in each channel, while maintaining a low energy barrier for transfer of carriers between the channels, according to the preferred embodiment of the present invention.

Block 800 represents placing dopant impurities at each heterointerface with a polarization charge, equal in magnitude to the polarization charge.

Specifically, for a heterostructure where n-type conductivity is desired, block 800 represents placing n-type dopant impurities at each heterointerface with negative polarization charge, equal in magnitude to the negative polarization charge. Alternatively, for a heterostructure where p-type conductivity is desired, block 800 represents placing p-type dopant impurities at each heterointerface with positive polarization charge, equal in magnitude to the positive polarization charge.

Preferably, the heterostructure is comprised of alternating AlGaN and GaN layers, alternating Al(x)Ga(1-x)N and Al(y)Ga(1-y)N layers where an Al composition x is larger than an Al composition y, or alternating Al(x)In(y)B(z)Ga(1-x-y-z)N layers where x, y, z are chosen to give a band-gap discontinuity between adjacent layers.

The dopant impurities, when ionized, serve to compensate the polarization charge, thus eliminating band-curvature at the heterointerface. Moreover, the dopant impurities serve to provide charge for the channels located at the heterointerfaces.

Block 802 represents comprising modifying the dopant impurities distribution, in order to tailor a shape of a conduction band edge.

The heterointerfaces may be graded in chemical composition, over a certain distance, while the dopant impurities are distributed along the graded distance. The heterointerfaces may have a non-linear, non-uniform or abrupt change in composition over the graded distance. When the heterointerfaces are abrupt, the dopant impurities are located in a sheet or a thin layer at or near the heterointerface. Moreover, portions of the graded distance may be undoped.

The heterointerfaces may be over-doped, so that a doping magnitude exceeds that of the polarization charge. Conversely, the heterointerfaces may be under-doped, so that a doping magnitude is lower than that of the polarization charge.

Possible Modifications

Possible modifications include:
1. The structure has three or more channels.
2. The n-type doping is performed with other shallow donor element than Si.
3. The doped heterointerfaces have a non-linear change in Al composition over a distance.
4. The doped heterointerfaces have a non-uniform change in Al composition over a distance.
5. The doped heterointerfaces have an abrupt change in Al composition, instead of a gradual change, over a distance.
6. Portions of the graded distance during which the Al composition is changed are undoped.
7. The doping in the graded distances in which the Al composition is changed is not uniform.
8. Heterointerfaces are over-doped (so that a doping magnitude exceeds that of the polarization charge).
9. Heterointerfaces are under-doped (so that a doping magnitude is lower than that of the polarization charge).
10. Doping at the interface includes sheets of doping (delta-doping).
11. Doping is placed near the heterointerface instead of at the heterointerface.
12. Different heterointerfaces may have different amounts of doping.
13. The heterointerfaces with positive polarization charge are doped with p-type impurities, instead of n-type doping heterointerfaces with negative polarization charge.
14. The heterostructure is comprised of alternating Al(x)Ga(1-x)N and GaN layers.
15. The heterostructure is comprised of alternating Al(x)Ga(1-x)N and Al(y)Ga(1-y)N layers, where an Al composition x is larger than an Al composition y.
16. The heterostructure is comprised of alternating Al(x)In(y)B(z)Ga(1-x-y-z)N layers, where x, y, z are chosen to give a band-gap discontinuity between adjacent layers.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A method for fabricating multiple channel heterostructures with high sheet carrier densities in each channel, while maintaining a low energy barrier for transfer of carriers between the channels, comprising:
for a heterostructure where n-type conductivity is desired, placing n-type dopant impurities at each heterointerface with negative polarization charge, equal in magnitude to the negative polarization charge.

2. The method of claim 1, wherein the n-type dopant impurities, when ionized, serve to compensate the negative polarization charge, thus eliminating band-curvature at the heterointerface.

3. The method of claim 1, wherein the n-type dopant impurities serve to provide charge for the channels located at the heterointerfaces with positive polarization charge.

4. The method of claim 1, further comprising modifying the n-type dopant impurities distribution, in order to tailor a shape of a conduction band edge.

5. The method of claim 1, wherein the heterointerfaces with negative polarization charge are graded in chemical composition, over a certain distance, while the n-type dopant impurities are distributed along the graded distance.

6. The method of claim 5, wherein the heterointerfaces with negative polarization charge have a non-linear change in composition over the distance.

7. The method of claim 5, wherein the heterointerfaces with negative polarization charge have a non-uniform change in composition over the distance.

8. The method of claim 5, wherein the heterointerfaces with negative polarization charge have an abrupt change in composition over the distance.

9. The method of claim 5, wherein portions of the graded distance are undoped.

10. The method of claim 1, wherein the heterointerfaces with negative polarization charge are abrupt, and the n-type dopant impurities are located in a sheet or a thin layer at or near said heterointerfaces.

11. The method of claim 1, wherein the heterointerfaces with negative polarization charge are over-doped, so that a doping magnitude exceeds that of the polarization charge.

12. The method of claim 1, wherein the heterointerfaces with negative polarization charge are under-doped, so that a doping magnitude is lower than that of the polarization charge.

13. The method of claim 1, wherein the heterostructure is comprised of alternating Al(x)Ga(1-x)N and GaN layers.

14. The method of claim 1, wherein the heterostructure is comprised of alternating Al(x)Ga(1-x)N and Al(y)Ga(1-y)N layers, where an Al composition x is larger than an Al composition y.

15. The method of claim 1, wherein the heterostructure is comprised of alternating Al(x)In(y)B(z)Ga(1-x-y-z)N layers, where x, y, z are chosen to give a band-gap discontinuity between adjacent layers.

16. A device fabricated using the method of claim 1.

17. A multiple channel heterostructure with high sheet carrier densities in each channel, that maintains a low energy barrier for transfer of majority carriers between the channels, comprising:
a plurality of layers having n-type dopant impurities placed at a heterointerface between layers with negative polarization charge, equal in magnitude to the negative polarization charge.

18. A method for fabricating multiple channel heterostructures with high sheet carrier densities in each channel, while maintaining a low energy barrier for transfer of carriers between the channels, comprising:
for a heterostructure where p-type conductivity is desired, placing p-type dopant impurities at each heterointerface with positive polarization charge, equal in magnitude to the positive polarization charge.

19. The method of claim 18, wherein the p-type dopant impurities, when ionized, serve to compensate the positive polarization charge, thus eliminating band-curvature at the heterointerface.

20. The method of claim 18, wherein the p-type dopant impurities serve to provide charge for the channels located at the heterointerfaces with negative polarization charge.

21. The method of claim 18, further comprising modifying the p-type dopant impurities distribution, in order to tailor a shape of a valence band edge.

22. The method of claim 18, wherein the heterointerfaces with positive polarization charge are graded in chemical composition, over a certain distance, while the p-type dopant impurities are distributed along the graded distance.

23. The method of claim 22, wherein the heterointerfaces with positive polarization charge have a non-linear change in composition over the distance.

24. The method of claim 22, wherein the heterointerfaces with positive polarization charge have a non-uniform change in composition over the distance.

25. The method of claim 22, wherein the heterointerfaces with positive polarization charge have an abrupt change in composition over the distance.

26. The method of claim 22, wherein portions of the graded distance are undoped.

27. The method of claim 18, wherein the heterointerfaces with positive polarization charge are abrupt, and the p-type dopant impurities are located in a sheet or a thin layer at or near said heterointerfaces.

28. The method of claim 18, wherein the heterointerfaces with positive polarization charge are over-doped, so that a doping magnitude exceeds that of the polarization charge.

29. The method of claim 18, wherein the heterointerfaces with positive polarization charge are under-doped, so that a doping magnitude is lower than that of the polarization charge.

30. The method of claim 18, wherein the heterostructure is comprised of alternating Al(x)Ga(1-x)N and GaN layers.

31. The method of claim 18, wherein the heterostructure is comprised of alternating Al(x)Ga(1-x)N and Al(y)Ga(1-y)N layers, where an Al composition x is larger than an Al composition y.

32. The method of claim 18, wherein the heterostructure is comprised of alternating Al(x)In(y)B(z)Ga(1-x-y-z)N layers, where x, y, z are chosen to give a band-gap discontinuity between adjacent layers.

33. A device fabricated using the method of claim 18.

34. A multiple channel heterostructure with high sheet carrier densities in each channel, that maintains a low energy barrier for transfer of majority carriers between the channels, comprising:
a plurality of layers having p-type dopant impurities placed at a heterointerface between layers with positive polarization charge, equal in magnitude to the positive polarization charge.
